(19) United States
(12) Patent Application Publication
(10) Pub. No.: US 2025/0216182 A1
(43) Pub. Date: Jul. 3, 2025

(54) LOCATION-TRACKING PROJECTILE ATTACHMENT FOR PURSUING FLEEING VEHICLE, CASE FOR CHARGING SAME, AND LOCATION-TRACKING SYSTEM INCLUDING SAME

(71) Applicant: GIST(Gwangju Institute of Science and Technology), Gwangju (KR)

(72) Inventors: Jongho LEE, Gwangju (KR); Sungbum CHO, Gwangju (KR); Changeui HONG, Gwangju (KR); Myeonggyun KIM, Gwangju (KR); Hyungwook YOO, Gwangju (KR); Jeahn Moch HAN, Gwangju (KR)

(73) Assignee: GIST(Gwangju Institute of Science and Technology), Gwangju (KR)

(21) Appl. No.: 19/051,509

(22) Filed: Feb. 12, 2025

Related U.S. Application Data
(63) Continuation-in-part of application No. PCT/KR2023/008896, filed on Jun. 27, 2023.

(30) Foreign Application Priority Data
Jun. 23, 2023 (KR) 10-2023-0081327

(51) Int. Cl. F42B 12/36

(52) U.S. Cl. CPC F42B 12/365

(57) ABSTRACT

The present disclosure relates to a location-tracking projectile attachment for pursuing a fleeing vehicle, a case for charging same, and a location-tracking system including same. There is provided a location-tracking projectile attachment including: a head having predetermined viscosity to be able to be attached to an attachment target; and a body coupled to the head and accommodating electric parts therein.

### CROSS-REFERENCE TO RELATED PATENT APPLICATION

This application is a Continuation-in-part application of International Patent Application No. PCT/KR2023/008896, filed on Jun. 27, 2023, which claims the benefit of Korean Patent Application No. 10-2023-0081327, filed on Jun. 23, 2023, in the Korean Intellectual Property Office, the disclosure of which is incorporated herein in its entirety by reference.

### TECHNICAL FIELD

The present disclosure relates to a location-tracking projectile attachment for pursuing a fleeing vehicle, a case for charging same, and a location-tracking system including same.

### BACKGROUND ART

Location information must be continuously transmitted to find out and track the location and route of a fleeing vehicle. Physically tracking with a means of pursuit, including a pursuer, is desirable, but it is practically difficult to continuously track a fleeing vehicle. Accordingly, there is a need for a technology that attaches a tracking device at a relatively close distance and obtains escape information, such as location and route, through the information from the tracking device. In the related art, attachable tracking devices have also been introduced, but it has been reported that problems arise, such as ineffective attachment when launched and reduced reliability of transmitted information due to the attachment state. Accordingly, there is a need for research and development of methods and devices to provide more effective tracking means for pursuing fleeing vehicles or other escapers, and there is a need for a technology that can obtain more reliable tracking information by processing transmitted information.

### DISCLOSURE

### Technical Problem

An object according to an embodiment of the present disclosure is to be effectively attached to a tracking target and enable continuous information transmission.

An object according to an embodiment of the present disclosure is to provide a means that can supply power to the electric parts in an attachment attached to a tracking target and store power.

An object according to an embodiment of the present disclosure is to construct a system that tracks a tracking target on the basis of information that can be obtained by attaching an attachment to the tracking target.

### Technical Solution

The present disclosure relates to a location-tracking projectile attachment for pursuing a fleeing vehicle, a case for charging same, and a location-tracking system including same. There is provided a location-tracking projectile attachment including: a head having predetermined viscosity to be able to be attached to an attachment target; and a body coupled to the head and accommodating electric parts therein.

Further, the head may include at least an adhesive substance and may be composed of different elastic materials.

Further, at least one layer including an adhesive substance of different elastic materials may form an attachment area and the other one elastic material may form a cushioning portion.

Further, the cushioning portion may be configured such that a material higher in elasticity is disposed at a center and a material relatively lower in elasticity extends a predetermined distance inward from an outer circumferential surface and has a triangular cross-section.

Further, the head may have through-holes or guide surfaces forming streamlines from a launching direction to an outer circumferential surface.

Further, the body may include: a connecting plate having a coupling mesh formed at an end and coupled to the head; an upper cylinder coupled at an end to the connecting plate; a lower cylinder coupled to another end of the upper cylinder; a cushioning portion accommodated in an internal space in which the upper cylinder and the lower cylinder are coupled; an extension extending outward from the lower cylinder in contact with the cushioning portion in the internal space; and a frame coupled to an extension end of the extension by a coupling portion and accommodating the electric parts.

Further, the body may include: a connecting plate having a coupling mesh formed at an end and coupled to the head; a rotary plate coupled to an inner side of the connecting plate; a slider connected to the rotary plate through a bearing; a protrusion inserted in a core of the slider with at least partial area disposed through the cushioning portion; and a frame on which the protrusion is seated and that accommodates the electric parts.

Further, the body may include: a frame accommodating the electric parts; an accommodating bracket having a coupling mesh formed at an end to be coupled to the head and accommodating at least a portion of the head; a fixed bracket in which the accommodating bracket is seated and that is fixed with the frame; a rotary plate that is coupled to the accommodating bracket and through which a protrusion protruding from the frame passes; and a cushioning portion radially interposed around the protrusion between the rotary plate and the frame.

Further, the location-tracking projectile attachment may further include a snap-fit protruding from an outer circumferential surface of the fixed bracket and being open in a launching direction, and a second snap-fit protruding from an inner circumferential surface of the frame and formed in a pattern corresponding to the first snap-fit to be able to be coupled.

Further, the body may include: a frame accommodating the electric parts; a slider fitted on a protrusion protruding from the frame; a cushioning bracket being able to reciprocate in contact with an outer circumferential surface of the slider; one or more O-rings interposed in a partial section between the cushioning bracket and the slider; and a cushioning portion fitted on the protrusion and interposed between the slider and the frame.

Further, the location-tracking projectile attachment may further include at least one or more cut portions cut in a direction in which the fixed bracket is inserted into the frame, and snap-locks protruding inward from an inner side of the frame at positions corresponding to the cut portions.

Further, a reinforcing portion having a honeycomb structure may be formed in at least a partial section of at least any one surface of an inner circumferential surface and an outer circumferential surface of the body.

Further, at least an edge of an inner side adjacent to the head of inner sides of the frame may include a curved surface portion formed as a curved surface.

Further, an edge adjacent to the head among edges formed on an outer surface of the body may include a curved surface.

There is provided a case in which the location-tracking projectile attachment is seated and charged. The case includes: an accommodation hole corresponding to the body; a sensor sensing whether the body is seated; and a power connector connected to a power supply.

Further, a guide protrusion corresponding to a spiral guide groove formed on an outer circumferential surface of the body is formed on an inner circumferential surface of the accommodating hole.

There is provided a location-tracking system that collects a location and a route of a tracking target through the location-tracking projectile attachment. The location-tracking system includes: a tracking module collecting information including geographic information; a web server storing information collected from the tracking module; and a terminal displaying a location and a route of the tracking target through the web server.

Further, the location-tracking system may perform a data collection step by a GPS module included in the tracking module, a speed measurement step of measuring a speed through collected data, and a determining step of determining the measured speed on the basis of a preset reference; may perform a database storage step of receiving and storing data satisfying the reference set in advance in the determining step by means of the web server and a locating step of finding out a location of a launched attachment requested from the terminal among the data stored in the database on the basis of a map API; and may perform a location display step of displaying location information found out through the locating step as an image by means of the terminal.

Further, the preset reference may be determined as being satisfied when the measured speed exceeds a set reference value.

Further, the attachment may be provided such that an identification substance is exposed on an area facing the attachment target, and the identification substance may be one of a fluorescent substance, a substance that is shown by an ultraviolet light source, a substance that is shown through thermal sensing, and a substance that is shown by corroding paint and metal plating.

Further, the head may be formed by stacking multiple layers having different properties, the attachment portion and a composite layer in which a cushioning material and a variable material are mixed may be stacked, and the composite layer may be configured, selectively, by sequentially stacking a cushioning layer made of the cushioning material and a variable layer made of the variable material.

Further, the composite layer may include a magnet therein, and the magnet may be disposed to be adjacent to the attachment portion.

Further, an adhesive area of the attachment portion may radially expand by a predetermined rotational force in launching.

Further, the head may further include a side wall formed to surround an outer circumferential surface of the attachment portion for uniform expansion by a rotation force in launching, and made of a substance having a higher elasticity modulus than the adhesive substance.

### Advantageous Effects

According to an embodiment of the present disclosure, it is possible to provide a location-tracking projectile attachment for pursuing a fleeing vehicle that is effectively attached to a tracking target and can continuously transmit information.

According to an embodiment of the present disclosure, it is possible to provide a means that can supply power to the electric parts in an attachment attached to a tracking target and store power.

According to an embodiment of the present disclosure, it is possible to provide a location-tracking system that tracks a tracking target on the basis of information that can be obtained by attaching an attachment to the tracking target.

### DESCRIPTION OF DRAWINGS

FIG. 1 is a perspective view showing an attachment according to an embodiment of the present disclosure.

FIG. 2A and FIG. 2B are views showing the state in which an attachment according to an embodiment of the present disclosure has been attached to an attachment surface by its head part.

FIG. 3A and FIG. 3B are views showing other embodiments of the head part according to an embodiment of the present disclosure.

FIG. 4 is a cross-sectional view showing the structure of a body according to an embodiment of the disclosure.

FIG. 5A is a view showing a body according to a first embodiment of the present disclosure.

FIG. 5B is a cross-sectional view of the body shown in FIG. 5A.

FIG. 6A is a view showing a body according to a second embodiment of the present disclosure.

FIG. 6B is a cross-sectional view of the body shown in FIG. 6A.

FIG. 7A is a view showing a body according to a third embodiment of the present disclosure.

FIG. 7B is a cross-sectional view of the body shown in FIG. 7A.

FIG. 8 is an exploded perspective view of the third embodiment of the present disclosure.

FIG. 9A is a view showing a body according to a fourth embodiment of the present disclosure.

FIG. 9B is a cross-sectional view of the body shown in FIG. 9A.

FIG. 10 is an exploded perspective view of the fourth embodiment of the present disclosure.

FIG. 11 is a view showing a case in which an attachment that is an embodiment of the present disclosure is accommodated.

FIG. 12 is a view showing a curved surface formed on a body that is an embodiment of the present disclosure.

FIG. 13 is an exploded perspective view showing the structure of a bracket to which electric parts are fixed and that is installed with the electric parts in a body that is an embodiment of the present disclosure.

FIG. 14 is a view showing a flowchart for explaining operation of a location-tracking system that tracks location using an attachment that is an embodiment of the present disclosure.

FIG. 15A is a view showing the structure of a body according to a fifth embodiment of the present disclosure.

FIG. 15B is a cross-sectional view of the body shown in FIG. 15A.

FIG. 16A and FIG. 16B are views showing the function of an O-ring in the fifth embodiment of the present disclosure.

FIG. 17A and FIG. 17B are views showing expansion of an attachment of the present disclosure by a rotational force.

FIG. 18 is a cross-sectional view of a head part according to another embodiment of the present disclosure.

FIG. 19 is a picture showing a launched state of a location-tracking projectile attachment having a head part without a sidewall.

FIG. 20 is a picture showing an attachment state in which a location-tracking projectile attachment having a head part without a sidewall has been attached to an attachment target.

FIG. 21 is a picture showing a launched state of a location-tracking projectile attachment having a head part with a sidewall.

FIG. 22 is a picture showing an attachment state in which a location-tracking projectile attachment having a head part with a sidewall has been attached to an attachment target.

FIG. 23 is a picture showing the state in which a head part without a sidewall has been separated from an attachment target.

FIG. 24 is a picture showing the state in which a head part with a sidewall has been separated from an attachment target.

FIG. 25 is a view showing the case in which a magnet having magnetism is disposed in an attachment of the present disclosure.

FIG. 26A, FIG. 26B, and FIG. 26C are views showing the function of a variable layer of an attachment of the present disclosure.

FIG. 27A and FIG. 27B are views showing embodiments of a composite layer of an attachment of the present disclosure.

### MODE FOR INVENTION

Hereafter, detailed embodiments of the present disclosure are described. However, these are only examples and the present disclosure is not limited thereto.

In description of the present disclosure, well-known technologies are not described in detail not to obscure the description of the present disclosure with unnecessary detail. Further, the following terminologies are defined in consideration of the functions in the present disclosure and may be construed in different ways by the intention or practice of users and operators. Therefore, the definitions thereof should be construed based on the contents throughout the specification.

The spirit of the present disclosure is determined by claims and the following embodiments are provided only to effectively explain the spirit of the present disclosure to those skilled in the art.

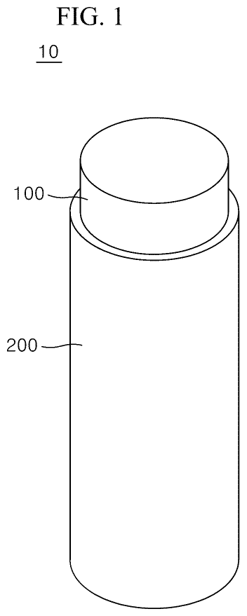

FIG. 1 is a perspective view showing an attachment 10 according to an embodiment of the present disclosure.

Referring to FIG. 1, an attachment 10 of an embodiment of the present disclosure includes a head 100 having predetermined viscosity to be able to be attached to an attachment target and a body 200 coupled to the head 100 and accommodating electric parts therein. The rigid body 200 may be configured with hardness that can support it so that it can be launched by a launching device and, for launching, the head 100 may be disposed in the launching device to face the launching direction. The head 100 has viscosity and elasticity and may be configured such that at least the portion having viscosity is exposed on the outer surface to face the launching direction.

Accordingly, the outer surface of a vehicle may be an example of an attachment target and the head 100 can be attached to the outer surface of the vehicle. Electric parts are provided in the body 200 and can transmit received and sensed information to the outside.

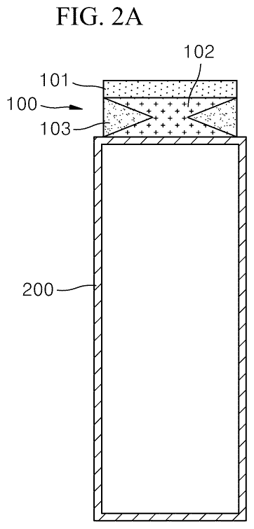

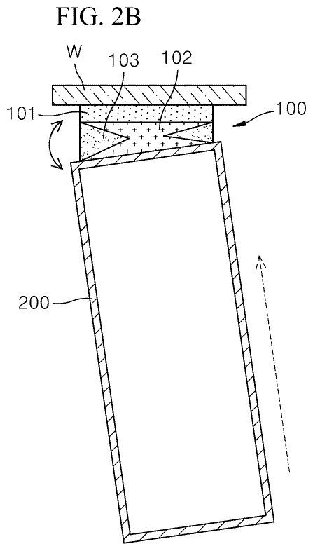

FIG. 2A and FIG. 2B are views showing that an attachment 10 according to an embodiment of the present disclosure is attached to an attachment surface W by its head part 100.

Referring to figures, the head 100 may include an attachment portion 101 disposed to face the attachment surface W. The attachment portion 101 has viscosity and is attached to the attachment surface W so that it can be continuously fixed by the adhesion. The attachment 10 can reach the attachment surface W through launching, and a cushioning structure may be provided on the rear of the attachment portion 101 to improve the attachment effect even though the trajectory of the attachment 10 is deviated at an angle from the direction that the attachment surface W faces.

The cushioning structure may be composed of a cushioning portion 102 and a cushioning material 103. The cushioning portion 102 is made of a material having higher elasticity than the cushioning material 103 and disposed at the center and the cushioning material 103 that is a material having relatively low elasticity may be formed on the outer circumferential surface of the cushioning portion 102 and may extend at predetermined distance inward from the outer circumferential surface. In this case, the cross-section of the cushioning material 103 may be formed in a triangular shape to easily change in correspondence to the angular spacing.

Further, the head 100 includes at least an adhesive substance and, in this embodiment, at least the attachment portion 101 may be made of an adhesive substance material. As described above, the head 100 may be configured such that at least one layer including an adhesive substance of different elastic materials forms an attachment area and the other one elastic material forms the cushioning structure.

Meanwhile, the attachment portion may include at least a fluorescent substance. The fluorescent substance may adopt a method in which a certain amount is included per unit volume, and may be provided to be exposed in the form of dots or lines on the exposed surface of the attachment portion 101 such that the fluorescent substance can be applied to the attachment surface W in attachment. In general, it is visible regardless of brightness (visible to the naked eye during the day and indicated in fluorescent form at night), but this form of the fluorescent substance is just an example and does not appear in a visible light environment. It can also be verified through a verification means with specific conditions as a substance that emits specific light or generates a specific wavelength.

For example, the coating material may be a fluorescent substance, but it can be verified by radiating ultraviolet light through a reaction with a specific component or it can be identified through thermal detection. Furthermore, by causing at least some corrosion of paint or metal plating, it can also be identified in the future even if tracking fails.

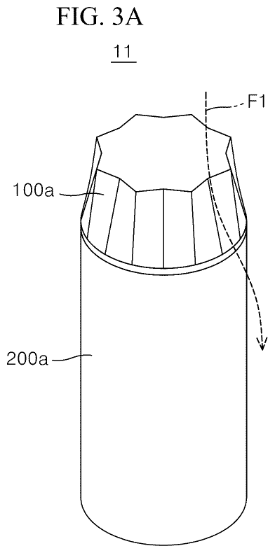

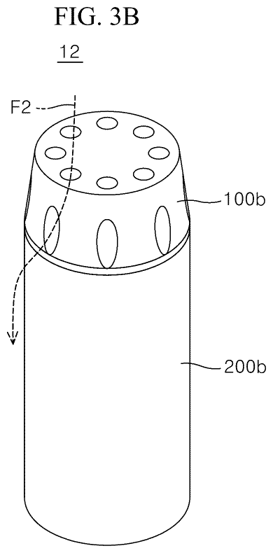

FIG. 3A and FIG. 3B are views showing other embodiments of the head part according to an embodiment of the present disclosure.

Referring to figures, heat parts 100a and 100b may have through-holes or guide surfaces forming streamlines F1 and F2 from the launching direction tot eh outer circumferential surface. These are design modification embodiments of the head 100, and in the case of FIG. 3A, a guide surface forming a first streamline F1 in a diagonal direction relative to the movement direction of the attachment 11 due to launching, which can increase accuracy in launching after aiming by reducing resistance in the air and improving flight stability. As a design modification of this purpose, in FIG. 3B, through-holes are formed in the head 100b in the diagonal direction such that second streamlines F2 passing through the through-holes can be formed.

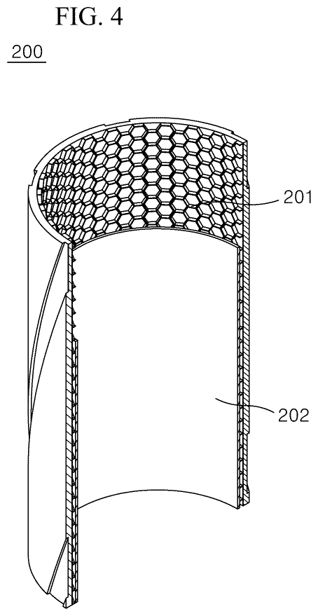

FIG. 4 is a cross-sectional view showing the structure of a body according to an embodiment of the disclosure.

Referring to FIG. 4, the body 200 that is coupled to heads 10, 11, and 12 of the various examples described above may have a reinforcing portion 201 formed in a honeycomb structure in at least a partial section of at least any one surface of the inner circumferential surface and the outer circumferential surface. This can be applied to the design as the ratio of the accommodating inner circumferential surface 202 and the reinforcing portion 201 of the part accommodating electric parts, and preferably, a formation section may be provided from an area adjacent to the head 100. This is a section where collision energy that is generated upon reaching the attachment W is first transmitted to the body, so the reinforcing portion 201 may be formed from the portion adjacent to the head 100 to be able to absorb the energy.

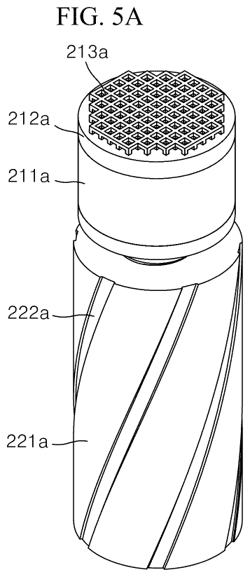

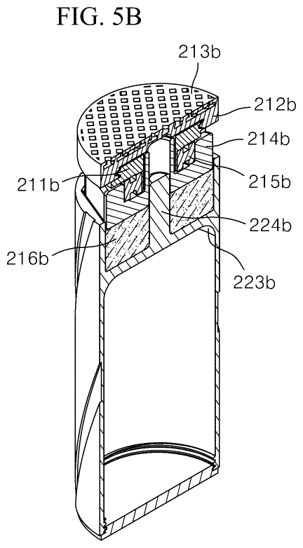

FIG. 5A and FIG. 5B are views showing a body 200b according to a first embodiment of the present disclosure.

Referring to figures, a body 200a may include a connecting plate 212a having a coupling mesh 213a formed at an end and coupled to the head 100, an upper cylinder 211a coupled at an end to the connecting plate 212a, a lower cylinder 214a coupled to another end of the upper cylinder 211a, a cushioning portion 217a accommodated in an internal space in which the upper cylinder 211a and the lower cylinder 214a are coupled, an extension 215a extending outward from the lower cylinder 214a in contact with the cushioning portion 217a in the internal space, and a frame (a component including an outer surface portion 221a and a guide groove 222a) coupled to the extension end of the extension 215a by a coupling portion 216a and accommodating electric parts. The extension 215a is formed in a T shape and is provided to be able to reciprocate in the internal space of the cylinders, and the cushioning portion 217a may be disposed in the internal space. Accordingly, when the head 100 reaches the attachment surface W, the movement speed rapidly decreases, so the cushioning portion 217a can attenuate generated shock while supporting the extension 215a.

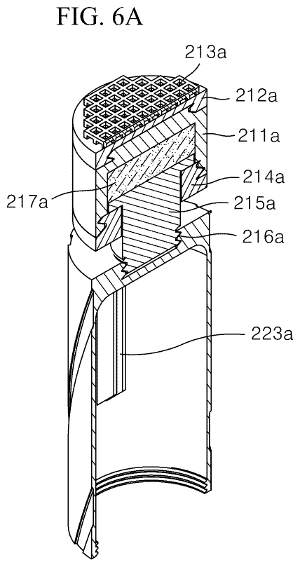

FIG. 6A and FIG. 6B are views showing a body 200b according to a second embodiment of the present disclosure.

Referring to figures, a body 200b may include a connecting plate 212b having a coupling mesh 213b formed at an end to be coupled to the head 100, a rotary plate 211b coupled to the inner side of the connecting plate 212b, a slider 214b connected to the rotary plate 211b through a bearing 215b, a protrusion 224b inserted in the core of the slider 214b with at least partial area disposed through the cushioning portion 217a, and a frame (a component including an outer surface portion 221b and a guide groove 222b) on which the protrusion 224b is seated and that accommodates electric parts.

Shock can be absorbed by the cushioning portion 216b when the head 100 is attached to the attachment W by the slider 214b that can reciprocated in the protrusion direction of the protrusion 224b. Further, rotation of the slider 214b can be restricted by an outer circumferential surface corresponding to a polygonal inner circumferential surface formed inside the upper end of the frame. However, the rotary plate 211b connected with the slider 214b through the bearing 215b is relatively rotated, whereby the connecting plate 212b and the coupling mesh 213b can be rotated. This can be rotated in the process in which it is launched along a guide groove 222b formed on the outer surface portion 221b of the frame and a rotation force generated in this case is prevented from being transmitted to the head 100, whereby a contact effect between the attachment surface W and the head 100 not rotating can be effectively generated in comparison to the heat 100 that is rotated.

An effect of preventing generation of shearing force due to torque generated at the time point of attachment can be expected from the structure that allows such relative rotation, and edges adjacent to the head 100 of the inner edges of the frame may be formed as curved surface portions 223b to prevent concentration of torque generated by rotation when the attachment 10 is launched. For example, when bending portions are formed, transmission force may be concentrated and this can be applied to various embodiments of the present disclosure.

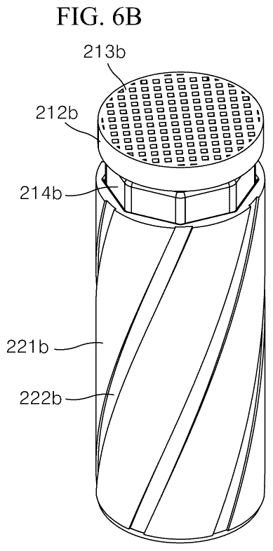

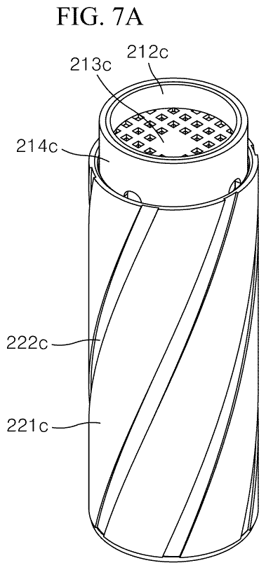

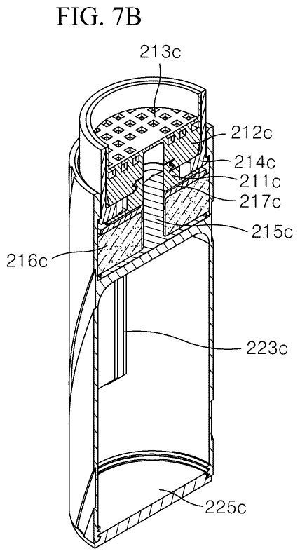

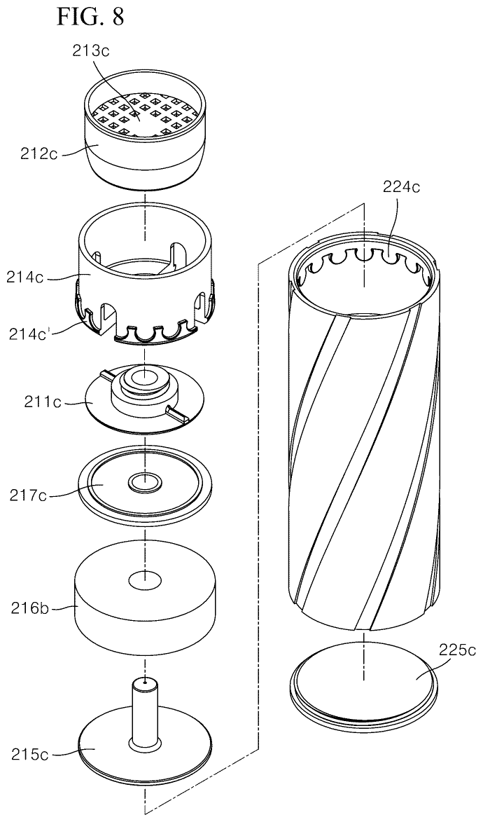

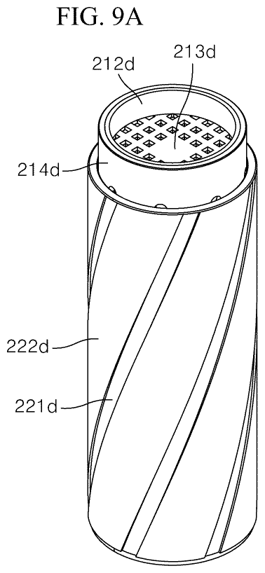

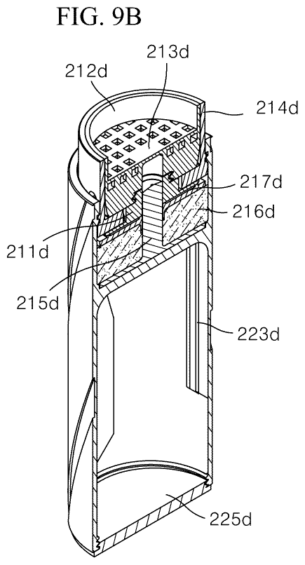

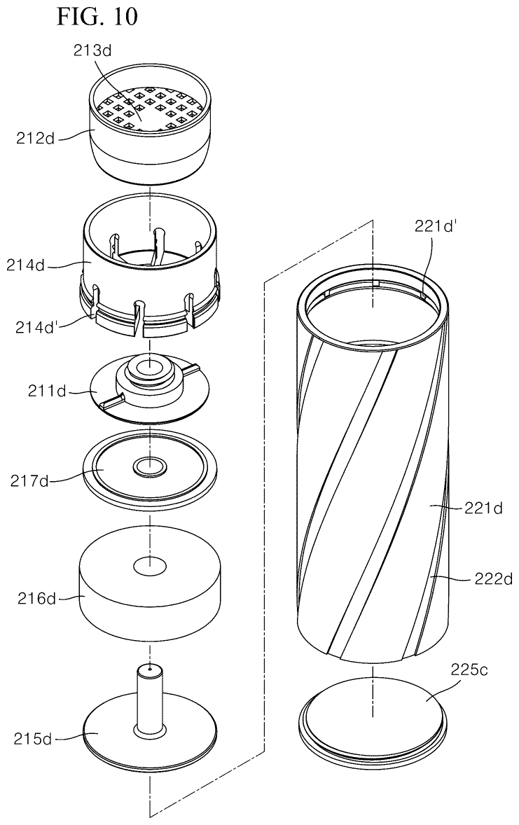

FIG. 7A and FIG. 7B are views showing a body 200c according to a third embodiment of the present disclosure. This is partially different from a body 200d according to a fourth embodiment of the present disclosure shown in FIG. 9A and FIG. 9B, and hereafter, common points are described, and the different features of the third embodiment and the fourth embodiment are described with reference to FIG. 8 and FIG. 10.

Referring to FIG. 7A and FIG. 7B, the body 200c may include a frame accommodating electric parts, an accommodating bracket 212c having a coupling mesh 213c formed at an end to be coupled to the head 100 and accommodating at least a portion of the head 100, a fixed bracket 214c in which the accommodating bracket 212c is seated and that is fixed with the frame, a rotary plate 211c that is coupled to the accommodating bracket 212c and through which a protrusion protruding from the frame passes, and a cushioning portion 216c radially interposed around the protrusion between the rotary plate 211c and the frame.

Further, a supporting plate 217c is in contact with the cushioning portion 216c facing the supporting plate 217c throughout the entire area, but the contact area with the rotary plate 211c that is the opposite side is formed to be relatively narrow through a protruding structure, whereby it is possible to maintain the angular momentum of the body. Further, through this structure that allows rotation, it is possible to prevent transmission of torsional stress of the body due to rapid variation of angular momentum in launching.

This may be a structure corresponding to torque that is generated in the attachment 10 in launching and attaching, and particularly, may be explanation of a structure in which snap coupling is removed by force, which is generated when the movement speed becomes 0 m/s in attaching, and the head is fixed in an adhesion state, but the body maintains rotation.

Through this structure, the third embodiment and the fourth embodiment can have a structure that prevents separation of some components from the body and attenuates shock generated in attaching.

FIG. 8 is an exploded perspective view of the third embodiment of the present disclosure.

Referring to FIG. 8, it may further include a snap-fit 214c′ protruding from the outer circumferential surface of the fixed bracket 214c and being open in the launching direction, and a second snap-fit 224c protruding from the inner circumferential surface of the frame and formed in a pattern corresponding to the first snap-fit 214c′ to be able to be coupled.

This can be coupled through snap-fit engagement in the assembly direction and configuration shown in the figures, and to this end, the fixed bracket 214c can have predetermined elasticity. For example, it may be made of a material including resin and plastic and it can be engaged by being inserted through some deformation in the coupling process and restored to fit the corresponding pattern.

FIG. 10 is an exploded perspective view of the fourth embodiment of the present disclosure.

Referring to FIG. 10, it may further include at least one or more cut portions 214d′ cut in the direction in which the fixed bracket 214d is inserted into the frame, and snap-locks 221d′ protruding inward from the inner side of the frame at positions corresponding to the cut portions 214d′. This serves to guide insertion and also serves to prevent rotation after insertion. That is, rotations are interlocked through coupling of the cut portions 214d′ and the snap-locks 221d′ in launching, whereby the med and the body can rotate or remaining non-rotating simultaneously.

This example can also prevent transmission of torsional stress of the body due to rapid variation of angular momentum in launching through the structure allowing rotation as in the examples of FIG. 7A, FIG. 7B, and FIG. 8 described above. This may be a structure corresponding to torque that is generated in the attachment 10 in launching and attaching, and particularly, may be explanation of a structure in which snap coupling is removed by force, which is generated when the movement speed becomes 0 m/s in attaching, and the head is fixed in an adhesion state, but the body maintains rotation.

Further, the fixed bracket 214d formed between not only the snap-locks 221d′, but the cut portions 214d′ has projections protruding outward and grooves corresponding thereto are formed on the inner surface of the frame, which can facilitate fixing in the insertion-coupling direction after coupling.

Of course, the features of the third embodiment and the fourth embodiment disclosed through FIG. 8 and FIG. 10 are configurations where one or more can be provided.

FIG. 11 is a view showing a case 300 accommodating the attachment 10 that is an embodiment of the present disclosure. Referring to FIG. 11, the attachment 10 described above may have electric parts, which performs a function for tracking a location, in a frame. The electric parts can perform communication and sensing functions by supply of power. To charge them through a wired/wireless means, the attachment 10 may be seated in the case 300 in which it can be inserted and stored and can be charged.

The case may have an accommodation hole so that the attachment 10 can be inserted and seated. Further, a case 300 including a sensor 320 sensing whether the body 200 is seated and a power connector 330 connected to a power supply may be provided. The power connector 330 may be formed on a side of the case 200 so that power can be supplied, and the sensor 320 may be provided on another side. The sensor 320 can sense seating at a normal depth or seating at a position where a battery can be charged, and can output information showing it. Further, a guide protrusion 311 corresponding to a spiral guide groove formed on an outer surface portion that is at least a portion of the body 200 may be formed on the inner circumferential surface of the accommodating hole.

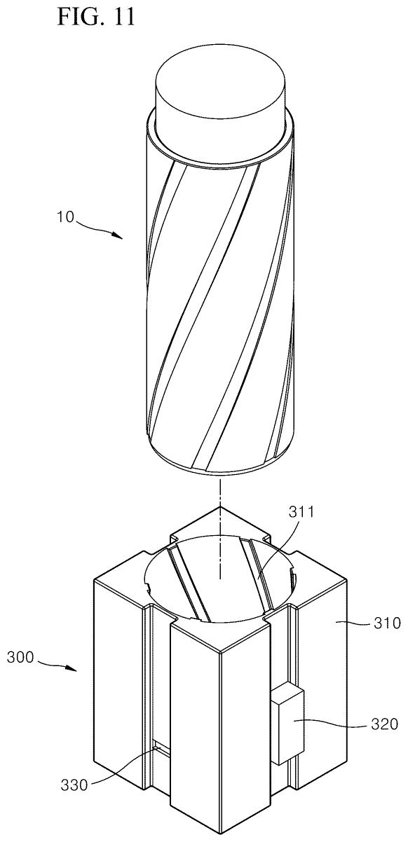

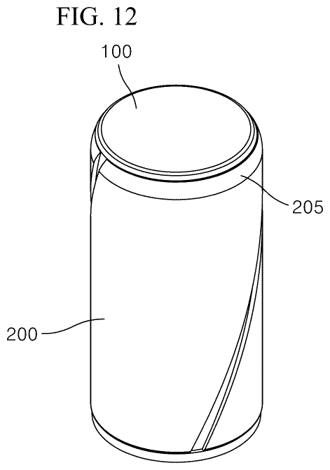

FIG. 12 is a view showing a curved surface 205 formed on the body 200 that is an embodiment of the present disclosure.

Referring to FIG. 12, the edge adjacent to the head 100 among the edges formed on the outer surface portion of the body 200 may include a curved surface 205. This is for preventing breakage of the attachment 10 that falls due to loss of adhesion and means replacing the tip with a curved surface to structurally reduce brittleness. In the same way as preventing damage, at least the edge of the inner side adjacent to the head of the inner sides of the frame may include a curved surface portion formed as a curved surface.

FIG. 13 is an exploded perspective view showing the structure of a bracket to which electric parts are fixed and that is installed with the electric parts in a body that is an embodiment of the present disclosure.

Referring to FIG. 13, electric parts such as a battery and a printed circuit board can be disposed at a first bracket 301, a second bracket 302, and a third bracket 303 through fixing and inserting, and they may be positioned in the internal space of the frame. In this case, the electric parts may be selectively included, if necessary, such as a GPS module sensing geographic information, a sensing unit, and a communication unit.

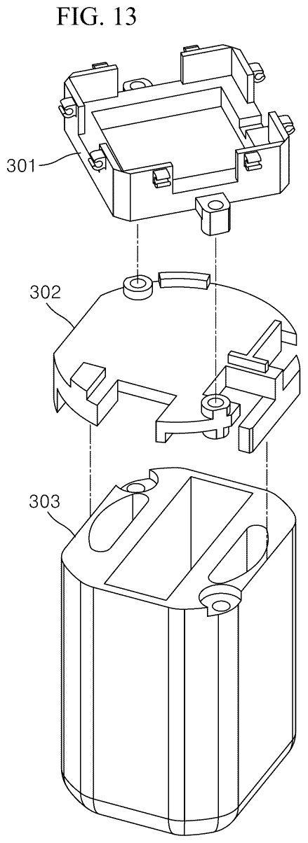

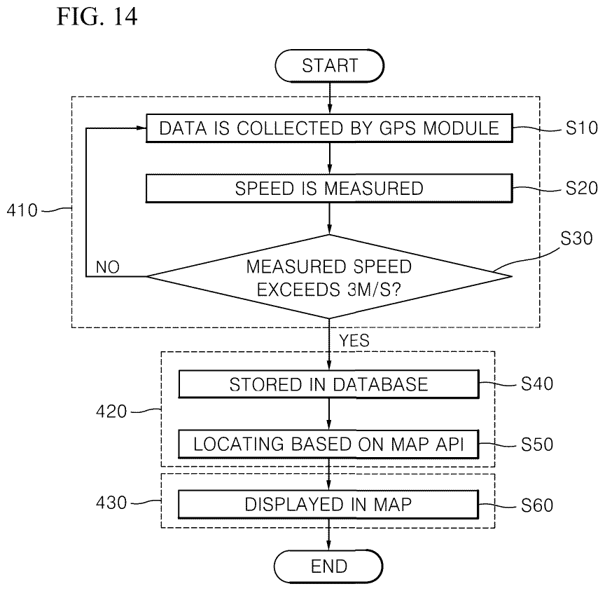

FIG. 14 is a view showing a flowchart for explaining operation of a location-tracking system that tracks location using an attachment that is an embodiment of the present disclosure.

Referring to FIG. 14, a location-tracking system according to an embodiment of the present disclosure may include a tracking module 410, a web server 420, and a terminal 430. The tracking module 410 may be an electric part disposed in the attachment 10. The components of the location-tracking system can perform the following functions.

The tracking module 410 collects information including geographic information, the web server 420 stores information collected from the tracking module, and the terminal 430 can display the location and route of a tracking target through the web server 420.

The tracking module 420 among the components can perform a data collection step S10 by a GPS module included in the tracking module, a speed measurement step S20 of measuring a speed through collected data, and a determining step S30 of determining the measured speed on the basis of a preset reference.

Next, it can perform a database storage step S40 of receiving and storing data satisfying the reference set in advance in determining step by means of the web server 420 and a locating step S50 of finding out the location of a launched attachment requested from the terminal among the data stored in the database on the basis of a map API. Finally, it can perform a location display step S60 of displaying the location information found out through the locating step as an image by means of the terminal 430.

In this case, it is determined that the preset reference is satisfied when the measured speed exceeds 3 m/s. That is, when an attachment target is moved, the movement speed and route are displayed, and when it is not moved or moved at a very low speed, data to be displayed on the terminal 430 is not created. This includes a purpose for efficiently using a battery because the process of collecting data rapidly consumes the battery, and for example, when the speed is 3 m/s or lower, the battery consumption speed can be delayed by not transmitting location information to the database. Of course, 3 m/s that is the preset reference is only an example and more sensitive setting is also possible to reducing it.

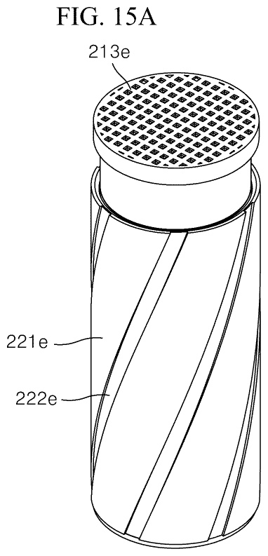

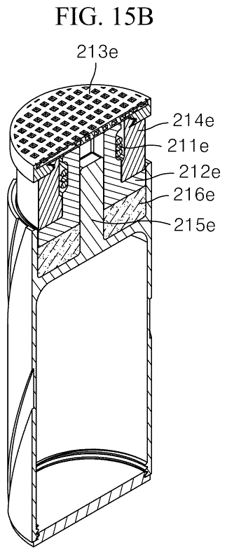

FIG. 15A and FIG. 15B are views showing the structure of a fifth embodiment of the present disclosure.

Referring to figures, the fifth embodiment of the present disclosure may include a frame accommodating electric parts, a slider 212e fitted on a protrusion 215e protruding from the frame, a cushioning bracket 214e being able to reciprocate in contact with the outer circumferential surface of the slider 212e, one or more O-rings 211e interposed in a partial section between the cushioning bracket 214e and the slider 212e, and a cushioning portion 216e fitted on the protrusion 215e and interposed between the slider 212e and the frame.

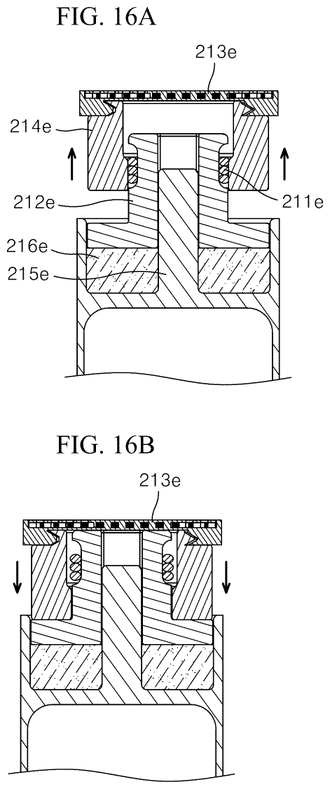

As shown in FIG. 16A and FIG. 16B, the fifth embodiment was designed such that one or more O-rings 211e are interposed and the cushioning bracket 214e can move forward and backward in the launching direction. When mounted on a launching device, the cushioning bracket 214e may be disposed to be drawn out forward, and in this case, when it is drawn out, the O-rings 211e can induce sliding while rotating between the cushioning bracket 214e and the slider 212e.

Further, the slider 212e is fitted on the protrusion 215e not to rotate. The protrusion 215e is configured in a polygonal shape and not rotated, so when a rotation force is transmitted to the body, the rotation force can be transmitted to the head. Since the protrusion 215e is formed in a polygonal shape and the inner circumferential surface of the slider 212e has a polygonal shape corresponding thereto, they can be coupled in response.

The O-ring 211e is interposed between the slider 212e and the cushioning bracket 214e and one or more O-rings may be provided, which may be considered as a structure in which when the cushioning bracket 214e is drawn out with respect to the slider 212e and fixed in the state, shock generated in attachment to an attachment surface after launching is primarily observed, and then the cushioning bracket 214e is contracted by the shock generated in attachment and the cushioning portion 216e can secondarily absorb the shock.

In this structure, the configuration used as the head 100 is the same as the above description and more detailed and various examples will be additionally described below.

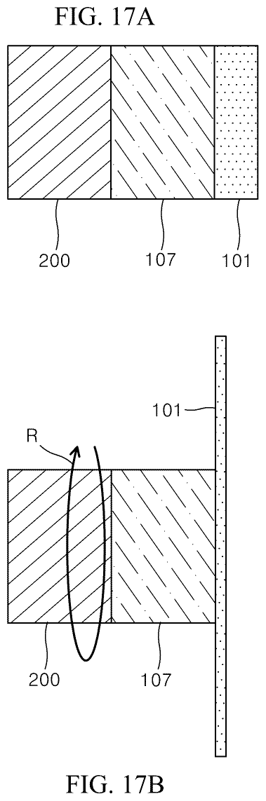

FIG. 17A and FIG. 17B are views showing expansion of an attachment 110 of the present disclosure by a rotational force.

Referring to figures, the attachment 101 is made of a soft material to be elastically deformed and restored by inertia. Further, the attachment 101 is made of an adhesive substance and the adhesive surface area can be expanded to be advantageous in adhesion. This effect allows an attachment portion 101′ to be expanded on the rotational radius of the attachment by a rotation force when the attachment 10 is launched with rotation, whereby the attachment portion 101′ can be an radially expanded attachment area.

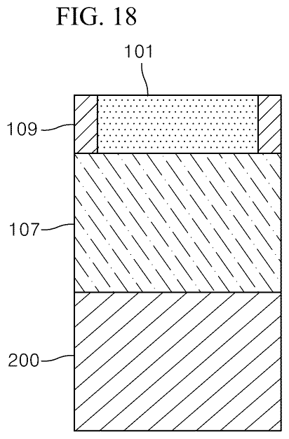

Meanwhile, a head part 100 according to another embodiment of the present disclosure is shown in FIG. 18.

Referring to figures, the head 100 further has a side wall 109 formed to surround the outer circumferential surface of the attachment portion 101 such that the attachment portion 101 is uniformly expanded by a rotation force during launching.

The side wall 109 has a predetermined thickness and is formed in a ring shape along the outer circumferential surface of the attachment portion 101, so it is coupled to the outer circumferential surface of the attachment portion 101. Further, the side wall 109 is formed with a height corresponding to the height of the attachment portion 101 and is open on the top surface such that the upper portion of the attachment portion 101 that faces an attachment target is exposed to the outside. Further, it is preferable that the side wall 109 is made of a soft elastomer having a higher elasticity modulus than the adhesive substance of the attachment portion 101.

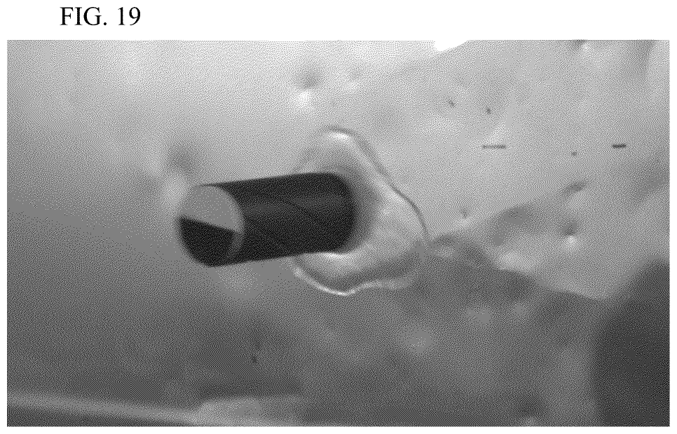

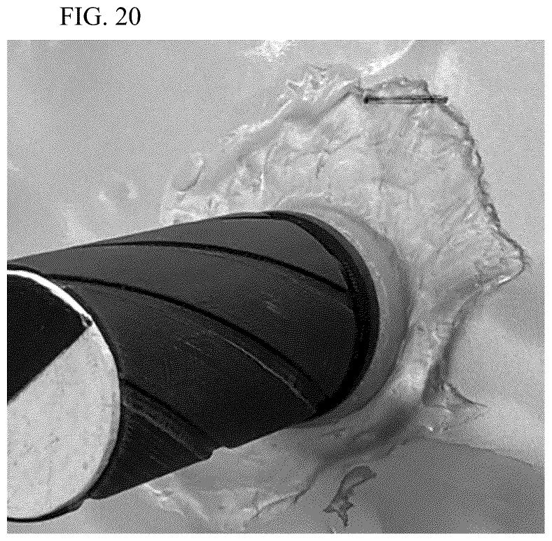

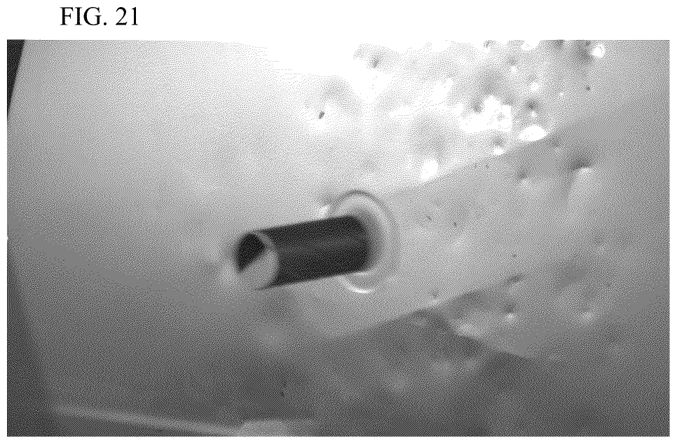

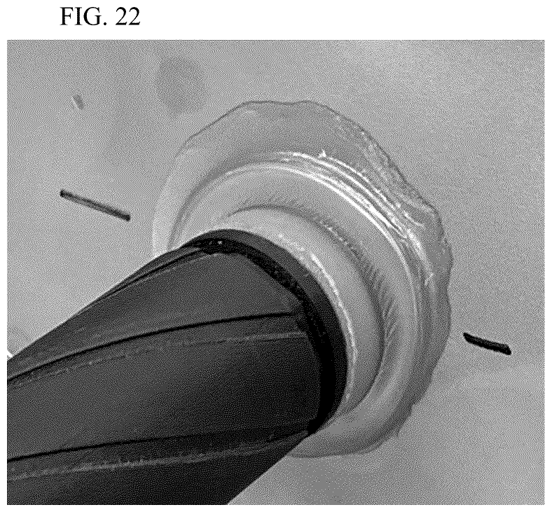

FIG. 19 is a picture showing a launched state of a location-tracking projectile attachment 10 having a head part 100 without a sidewall 109, FIG. 20 is a picture showing an attachment state in which a location-tracking projectile attachment 10 having a head part 100 without a sidewall 106 has been attached to an attachment target, FIG. 21 is a picture showing a launched state of a location-tracking projectile attachment 10 having a head part 100 with a sidewall 109, and FIG. 22 is a picture showing an attachment state in which a location-tracking projectile attachment 10 having a head part 100 with a sidewall 109 has been attached to an attachment target.

Referring to figures, in the launching process of a location-tracking projectile attachment having a head part 100 without a sidewall 109, the attachment portion 101 is not uniform and is widely expanded more than necessary and interferes with flight, and even when attached to an attachment target, the attachment portion 101 is not uniformly distributed, so the attachment strength may be deteriorated. However, in the launching process of a location-tracking projectile attachment having a head part 100 with a sidewall 109, the attachment portion 101 is uniformly expanded and is prevented from widely expanding more than necessary, whereby it is possible to maintain a stable flight trajectory. Further, even after reaching an attachment target, the attachment portion 101 is uniformly distributed on the attachment target, so it is possible to provide relatively excellent attachment strength.

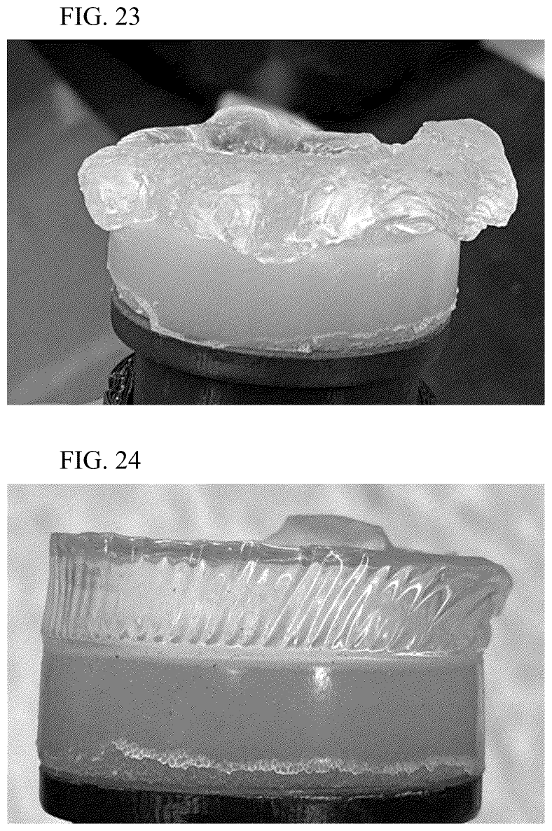

Meanwhile, FIG. 23 is a picture showing the state in which a head part 100 without a side wall 109 has been separated from an attachment target and FIG. 24 is a picture showing the state in which a head part 100 with a side wall has been separated from an attachment target.

Referring to figures, when the head part 100 without a side wall 109 is separated from an attachment target, it cannot be restored into the initial external shape, so structural damage is generated and it cannot be reused. On the other hand, the head part 100 with a side wall 109 is relatively restored into the initial state even after it is separated from an attachment target, so it can be reused.

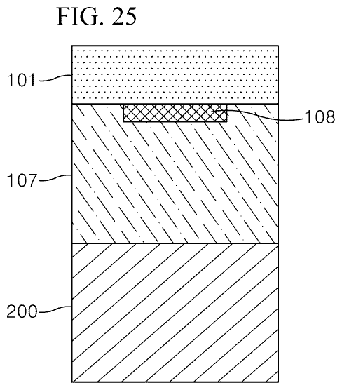

Meanwhile, as another embodiment of the head 100, a composite layer (supporting layer 107) includes a magnet 108 therein and the magnet 108 may be disposed to be adjacent to the attachment portion 101. In detail, the case in which a magnet 108 having magnetism is disposed in the attachment portion 101 is shown through FIG. 25, which can further reinforce the adhesion together with the attachment portion 101 in attachment when an attachment target is a vehicle and the structure constituting the surface including the doors of the vehicle is metal. When the magnet 108 is positioned in an attachment portion, the magnet 108 or the composite layer 105′ may be damaged in attachment when the embodiment that radially expanding in the above description is applied, so the magnet may be included in the composite layer 105′ and may be provided at a position adjacent to the attachment portion. For example, the magnet 108 may be exposed out of the composite layer 105′ such that a side can be in contact with the attachment portion 101.

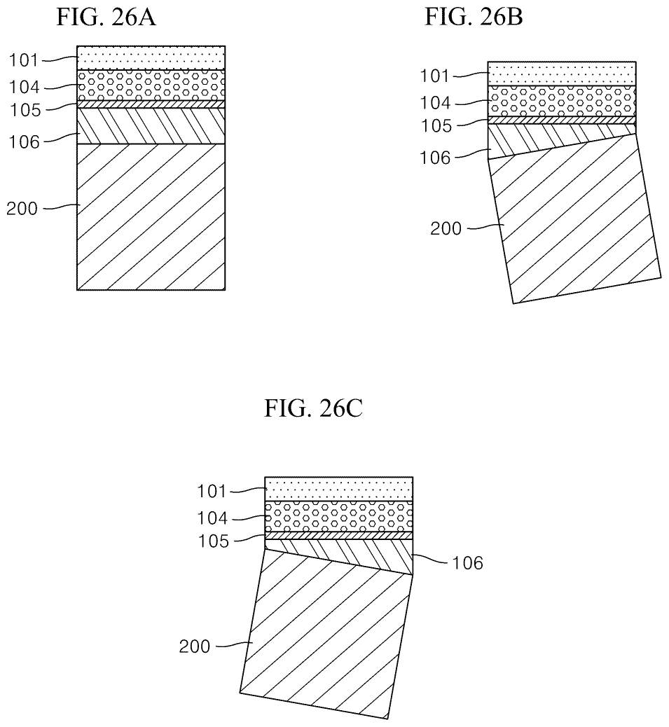

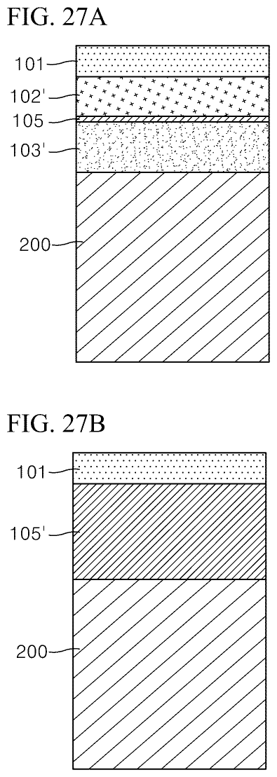

FIG. 26A, FIG. 26B, and FIG. 26C are views showing the function of a variable layer 106 of an attachment 10 of the present disclosure, and FIG. 27A and FIG. 27B are views showing embodiments of the composite layer 105′ of an attachment of the present disclosure.

Referring to figures, a head 100 may be formed by stacking multiple layers having different properties and may have a composite layer 105′ in which an attachment portion 101 and a composite layer 105′ in which a cushioning material (cushioning layer 104) and a variable material (variable layer 106) are mixed are stacked in the launching direction, and selectively, the composite layer 105′ may be configured by sequentially stacking a cushioning layer 104 made of the cushioning material and a variable layer 106 made of the variable material.

The composite layer 105′ may be configured by sequentially stacking single materials or different materials. In this case, the single material does not mean a material composed of a single molecule and, even if it is a composite material, it means a configuration formed without a separate boundary and without being stacked through physical or chemical bonding. For example, filling pores formed in a variable material with a fluid-type cushioning material and then hardening the cushioning material can be explained by the example of FIG. 20(b). As another example, in the case when a variable material and a cushioning material are separately provided and provided to be separated by forming layers, it may be the example shown in FIG. 20(a).

Both of the examples described above can achieve the effect, align with the purpose and intention of the example described above with reference to FIG. 3, and can implement the functions shown in FIG. 26A, FIG. 26B, and FIG. 26C. When reaching an attachment target in a diagonal direction, as in FIG. 26B or FIG. 26C, the cushioning material 104 can receive shock generated between the attachment 10 and the attachment target and the variable material 106 can vary to reduce reactant force while achieving it.

Although representative embodiments of the present disclosure were described above, those skilled in the art will understand that the embodiments may be modified in various ways without departing from the scope of the present disclosure. Therefore, the scope of the present invention should not be limited to the embodiment(s), but should be determined by not only the following claims, but equivalents of the claims.

1. A location-tracking projectile attachment comprising:
a head having predetermined viscosity to be able to be attached to an attachment target; and
a body coupled to the head and accommodating electric parts therein.

2. The location-tracking projectile attachment of claim 1, wherein the head includes at least an adhesive substance and is composed of different elastic materials.

3. The location-tracking projectile attachment of claim 2, wherein an attachment portion that is one layer including at least the adhesive substance of the different elastic materials is formed, and the other one or more elastic material forms a cushioning structure.

4. The location-tracking projectile attachment of claim 3, wherein in the cushioning structure, a cushioning portion higher in elasticity is disposed at a center and a cushioning material relatively lower in elasticity extends a predetermined distance inward from an outer circumferential surface and has a triangular cross-section.

5. The location-tracking projectile attachment of claim 1, wherein the head has through-holes or guide surfaces forming streamlines from a launching direction to an outer circumferential surface.

6. The location-tracking projectile attachment of claim 1, wherein the body includes:
a connecting plate having a coupling mesh formed at an end and coupled to the head;
an upper cylinder coupled at an end to the connecting plate;
a lower cylinder coupled to another end of the upper cylinder;
a cushioning portion accommodated in an internal space in which the upper cylinder and the lower cylinder are coupled;
an extension extending outward from the lower cylinder in contact with the cushioning portion in the internal space; and
a frame coupled to an extension end of the extension by a coupling portion and accommodating the electric parts.

7. The location-tracking projectile attachment of claim 1, wherein the body includes:
a connecting plate having a coupling mesh formed at an end and coupled to the head;
a rotary plate coupled to an inner side of the connecting plate;
a slider connected to the rotary plate through a bearing;
a protrusion inserted in a core of the slider with at least partial area disposed through the cushioning portion; and
a frame on which the protrusion is seated and that accommodates the electric parts.

8. The location-tracking projectile attachment of claim 1, wherein the body includes:
a frame accommodating the electric parts;
an accommodating bracket having a coupling mesh formed at an end to be coupled to the head and accommodating at least a portion of the head;
a fixed bracket in which the accommodating bracket is seated and that is fixed with the frame;
a rotary plate that is coupled to the accommodating bracket and through which a protrusion protruding from the frame passes; and
a cushioning portion radially interposed around the protrusion between the rotary plate and the frame.

9. The location-tracking projectile attachment of claim 8, further comprising a snap-fit protruding from an outer circumferential surface of the fixed bracket and being open in a launching direction, and a second snap-fit protruding from an inner circumferential surface of the frame and formed in a pattern corresponding to the first snap-fit to be able to be coupled.

10. The location-tracking projectile attachment of claim 8, further comprising at least one or more cut portions cut in a direction in which the fixed bracket is inserted into the frame, and snap-locks protruding inward from an inner side of the frame at positions corresponding to the cut portions.

11. The location-tracking projectile attachment of claim 1, wherein the body includes:
a frame accommodating the electric parts;
a slider fitted on a protrusion protruding from the frame;
a cushioning bracket being able to reciprocate in contact with an outer circumferential surface of the slider;
one or more O-rings interposed in a partial section between the cushioning bracket and the slider; and
a cushioning portion fitted on the protrusion and interposed between the slider and the frame.

12. The location-tracking projectile attachment of claim 1, wherein a reinforcing portion having a honeycomb structure is formed in at least a partial section of at least any one surface of an inner circumferential surface and an outer circumferential surface of the body.

13. The location-tracking projectile attachment of claim 7, wherein at least an edge of an inner side adjacent to the head of inner sides of the frame includes a curved surface portion formed as a curved surface.

14. The location-tracking projectile attachment of claim 1, wherein an edge adjacent to the head among edges formed on an outer surface of the body includes a curved surface.

15. A case in which the location-tracking projectile attachment of claim 1 is seated and charged, the case comprising:
an accommodation hole corresponding to the body;
a sensor sensing whether the body is seated; and
a power connector connected to a power supply.

16. The case of claim 15, wherein a guide protrusion corresponding to a spiral guide groove formed on an outer circumferential surface of the body is formed on an inner circumferential surface of the accommodating hole.

17. A location-tracking system that collects a location and a route of a tracking target through the location-tracking projectile attachment of claim 1, the location-tracking system comprising:
a tracking module collecting information including geographic information;
a web server storing information collected from the tracking module; and
a terminal displaying a location and a route of the tracking target through the web server.

18. The location-tracking system of claim 17, wherein the location-tracking system
performs a data collection step by a GPS module included in the tracking module, a speed measurement step of measuring a speed through collected data, and a determining step of determining the measured speed on the basis of a preset reference;
performs a database storage step of receiving and storing data satisfying the reference set in advance in the determining step by means of the web server and a locating step of finding out a location of a launched attachment requested from the terminal among the data stored in the database on the basis of a map API; and
performs a location display step of displaying location information found out through the locating step as an image by means of the terminal.

19. The location-tracking system of claim 18, wherein the preset reference is determined as being satisfied when the measured speed exceeds a set reference value.

20. The location-tracking projectile attachment of claim 3, wherein the attachment is provided such that an identification substance is exposed on an area facing the attachment target, and
the identification substance is one of a fluorescent substance, a substance that is shown by an ultraviolet light source, a substance that is shown through thermal sensing, and a substance that is shown by corroding paint and metal plating.

21. The location-tracking projectile attachment of claim 3, wherein the head is formed by stacking multiple layers having different properties,
the attachment portion and a composite layer in which a cushioning material and a variable material are mixed are stacked, and
the composite layer can be configured, selectively, by sequentially stacking a cushioning layer made of the cushioning material and a variable layer made of the variable material.

22. The location-tracking projectile attachment of claim 21, wherein the composite layer includes a magnet therein, and
the magnet is disposed to be adjacent to the attachment portion.

23. The location-tracking projectile attachment of claim 3, wherein an adhesive area of the attachment portion radially expands by a predetermined rotational force in launching.

24. The location-tracking projectile attachment of claim 23, wherein the head further includes a side wall formed to surround an outer circumferential surface of the attachment portion for uniform expansion by a rotation force in launching, and made of a substance having a higher elasticity modulus than the adhesive substance.
